(19) United States
(12) Patent Application Publication
(10) Pub. No.: US 2008/0315193 A1
(43) Pub. Date: Dec. 25, 2008

(54) Oxide-based thin film transistor, method of fabricating the same, zinc oxide etchant, and a method of forming the same

(75) Inventors: Chang-jung Kim, Yongin-si (KR); Young-soo Park, Yongin-si (KR); Eun-ha Lee, Seoul (KR); Jae-chul Park, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/149,409

(22) Filed: May 1, 2008

(30) Foreign Application Priority Data
Jun. 22, 2007 (KR) 10-2007-0061875

(51) Int. Cl. H01L 29/22; H01L 21/34; C09K 13/06; C09K 13/08

(52) U.S. Cl. 257/43; 438/104; 252/79.3; 252/79.4; 257/E21.46; 257/E29.094

(57) ABSTRACT

Provided is a zinc (Zn) oxide-based thin film transistor that may include a gate, a gate insulating layer on the gate, a channel including zinc oxide and may be on a portion of the gate insulating layer, and a source and drain contacting respective sides of the channel. The zinc (Zn) oxide-based thin film transistor may further include a recession in the channel between the source and the drain, and a zinc oxide-based etchant may be used to form the recession.

### PRIORITY STATEMENT

This application claims priority under 35 U.S.C. § 119 to Korean Patent Application No. 10-2007-0061875, filed on Jun. 22, 2007, in the Korean Intellectual Property Office (KIPO), the entire contents of which are incorporated herein by reference.

### BACKGROUND

1. Field

Example embodiments relate to a zinc (Zn) oxide-based thin film transistor and a zinc oxide-based etchant, and more particularly, to a zinc oxide-based thin film transistor, which may be formed with a zinc-oxide based etchant and/or without damaging a region of a channel. Other example embodiments relate to methods of fabricating a zinc oxide-based thin film transistor and methods of forming a zinc oxide-based etchant.

2. Description of the Related Art

Thin film transistors have a wide range of applications, e.g., switching and driving devices of displaying devices. Thin film transistors may be used as a selection switch of a cross point-type memory device. In thin film transistors, mobility or leakage currents may be dependent on a material and state of a channel layer.

Currently, ZnO-based thin film transistors may receive attention as oxide-based semiconductor devices. In ZnO-based thin film transistors, a channel region may be formed of a ZnO-based material, e.g., Zn oxide, InZn oxide, or GaInZn oxide. Accordingly, ZnO-based thin film transistors may be fabricated at relatively low temperature. In addition, because a ZnO-based thin film transistor may be in an amorphous state, ZnO-based thin film transistors may be formed over a relatively large area.

FIG. 1 is a view of a conventional thin film transistor. The conventional thin film transistor will now be described in detail with reference to FIG. 1. A gate 12 may be formed on a portion of an insulating layer 11 formed on a substrate 10. A gate insulating layer 13 may be formed on the substrate 10 and the gate 12. A channel 14 formed of a Zn oxide-based material may be formed on a portion of the gate insulating layer 13 corresponding to the gate 12. A source 15a and a drain 15b may be formed on sides of the gate 12.

In a process of fabricating a conventional thin film transistor, an electrode material may be deposited on the channel 14 and the gate insulating layer 13, and then, a dry or wet etching process may be performed to form the source 15a and the drain 15. The channel 14 may be damaged in the dry or wet etching process producing a damaged region 16. For example, a dry etching process may be performed using a plasma etching process. In the plasma etching process, the channel 14 that may be formed of a Zn oxide-based material may be damaged by plasma. On the other hand, in a wet etching process, an electrode material may remain on the surface or side surface of the channel 14 which may deteriorate electrical properties of the thin film transistor.

FIG. 2A is a graphical view of a drain current with respect to a gate voltage of a conventional thin film transistor when an active region is damaged by a plasma etching process while a source and drain are formed in the thin film transistor. Referring to FIG. 2A, when the thin film transistor is fabricated using a plasma etching process, a gate voltage may be applied and no thin film transistor characteristics may be exhibited. The graph of FIG. 2A may be linear, and may include an off-current of 10⁻⁶ A and an on-current of 10⁻⁴ A.

FIG. 2B is a graphical view of a drain current with respect to a gate voltage of a conventional thin film transistor when that an active region is damaged by a wet etching process while a source and drain are formed in the thin film transistor. Referring to FIG. 2B, the graph may have an off-current of about 10⁻¹³ A and an on-current of 10⁻³ A, and a curved shape having one step. The source 15a forming material or the drain 15b forming material may have been processed using an etching process that may remain on the surface of the channel 14 to adversely affect the electrical properties of the thin film transistor.

### SUMMARY

Example embodiments may provide a zinc (Zn) oxide-based thin film transistor having more stable electrical properties in which a damaged region is not formed. Example embodiments also may provide a zinc oxide-based etchant where an etching process of a zinc oxide-based material may be controlled.

According to example embodiments, a zinc oxide-based thin film transistor may include a gate, a gate insulating layer on the gate, a channel including zinc oxide on a portion of the gate insulating layer, and source and drain contacting sides of the channel. The zinc oxide-based thin film transistor may include a recession in the channel between the source and the drain. The recession may be formed to have a step with respect to portions of the channel contacting the source and the drain. The zinc oxide may be ZnO, InZnO, or GaInZnO.

According to example embodiments, a method of fabricating a thin film transistor may include providing a gate, forming a gate insulating layer on the gate, forming a channel including zinc oxide on a portion of the gate insulating layer, forming source and drain by coating a conductive material on the gate insulating layer and the channel and etching the conductive material on the channel, and forming a recession by etching a surface of the channel exposed between the source and the drain. Forming the recession by etching may include using a wet etching process using a zinc oxide-based etchant including an aqueous mixture solution of CH₃COOH and at least one of HCl, HF, and P₂O₅.

According to example embodiments, a zinc oxide-based etchant may include an aqueous mixture solution of CH₃COOH and at least one of HCl, HF, and P₂O₅. The amount of the least one of HCl, HF, and P₂O₅ may be in the range from about 0.1 to about 1 vol %. The amount of CH₃COOH may be in the range from about 5 to about 50 vol %. According to example embodiments, a method of forming a zinc oxide-based etchant may include mixing at least 1 ml of at least one of HCl, HF, and P₂O₅ with at least 99 ml of a deionized water and mixing at least 10 ml of CH₃COOH with the mixture of the at least one HCl, HF, and P₂O₅ and the deionized water.

### BRIEF DESCRIPTION OF THE DRAWINGS

The above and other features and advantages of example embodiments will become more apparent by describing in detail exemplary embodiments thereof with reference to the attached drawings in which:

FIG. 1 is a sectional view of a conventional thin film transistor;

FIG. 2A is a graphical view of a drain current with respect to a gate voltage of a conventional thin film transistor where an active region is damaged by a plasma etching process when a source and drain are formed in a thin film transistor;

FIG. 2B is a graphical view of a drain current with respect to a gate voltage of a conventional thin film transistor where an active region is damaged by a wet etching process when a source and drain are formed in the thin film transistor;

FIG. 3 is a view of a Zn oxide-based thin film transistor according to example embodiments;

FIGS. 4A through 4E are views illustrating a method of fabricating a Zn oxide-based thin film transistor according to example embodiments;

FIG. 5 is a graphical view of a drain current with respect to a gate voltage of a Zn oxide-based thin film transistor according to example embodiments;

FIGS. 6A and 6B illustrate images of the surface of a ZnO before and after a wet etching process is performed using a Zn oxide-based etchant according to example embodiments; and

FIG. 7 is a graphical view illustrating humidity test results when a thin film transistor is etched using a Zn oxide-based etchant according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. In the drawings, the thickness of layers, films and regions are exaggerated for clarity. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to described various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g. “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. Thus, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

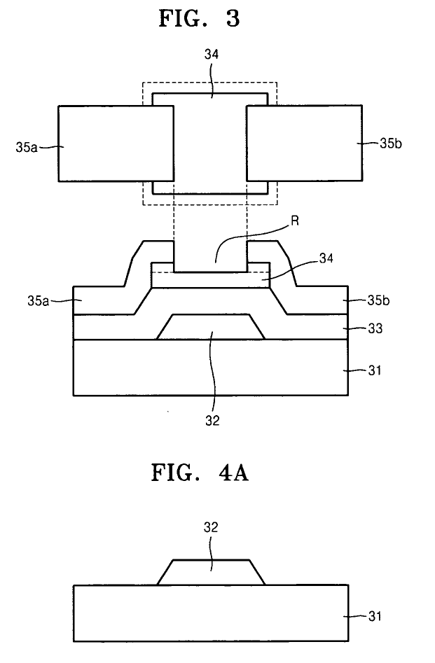

FIG. 3 is a view of a zinc (Zn) oxide-based thin film transistor according to example embodiments. Although FIG. 3 illustrates a bottom gate-type thin film transistor, example embodiments are not limited thereto. For example, a thin film transistor according to example embodiments may also be applied to a top gate-type thin film transistor. Referring to FIG. 3, a Zn oxide-based thin film transistor according to example embodiments may include a gate 32 formed on a portion of a substrate 31, a gate insulating layer 33 formed on the substrate 31 and gate 32, a channel 34 formed on a portion of the gate insulating layer 33 corresponding to the gate 32, and a source 35a and drain 35b contacting ends of the channel 34 on the gate insulating layer 33.

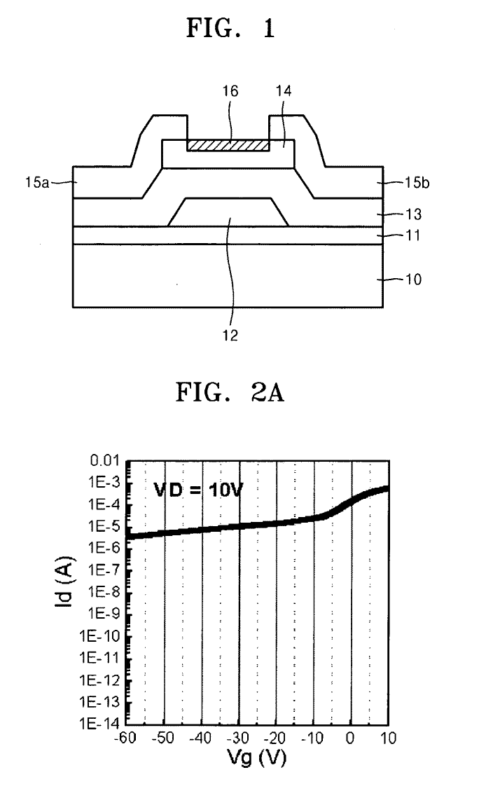

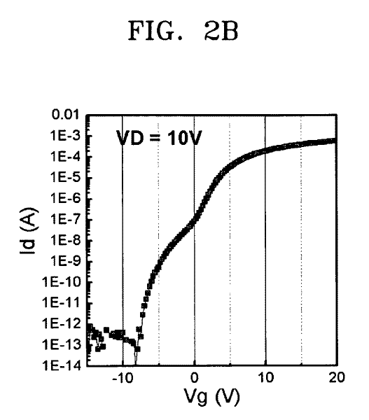

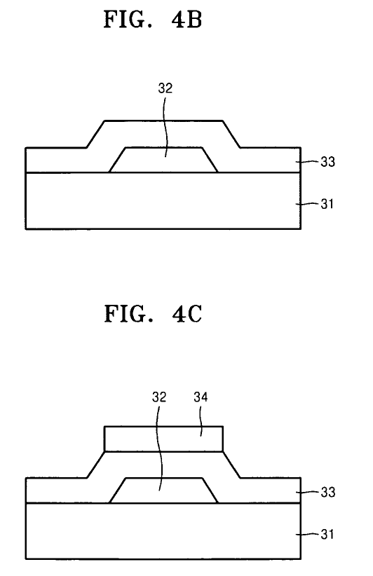

The Zn oxide-based thin film transistor according to example embodiments may include a recession R between the source 35a and the drain 35b in the channel 34. Specifically, the recession R may be a region obtained by etching a surface of the channel 34 that does not contact the source 35a and drain 35b. Accordingly, the recession R may be formed to have a step with respect to portions of the channel 34 contacting the source 35a and drain 35b. The recession R may be formed to stabilize electrical properties of a thin film transistor by removing the damaged region 16 formed in the channel 14 of the conventional thin film transistor illustrated in FIG. 1. A method of preparing a Zn oxide-based thin film transistor according to example embodiments will now be described in detail with reference to FIGS. 4A through 4E.

Referring to FIG. 4A, a gate 32 may be formed by coating and etching a conductive material on a portion of the substrate 31. The substrate 31 may be formed of silicon, glass, a plastic material, or an organic material. When the substrate 31 is formed of silicon, a surface of the substrate 31 may be thermally treated to form a silicon oxide. The gate 32 may be formed using a conductive material, e.g., metal or metal oxide.

Referring to FIG. 4B, an insulating material may be coated on the substrate 31 and the gate 32 to form a gate insulating layer 33. The gate insulating layer 33 may be formed using any insulating material that is suitable for a conventional method of fabricating a semiconductor device. For example, the gate insulating layer 33 may be formed using SiO₂, a high-k material which may have a higher dielectric constant than SiO₂, e.g. HfO₂, Al₂O₃, Si₃N₄, or a mixture thereof.

Referring to FIG. 4C, a channel 34 may be formed on a portion of the gate insulating layer 33 corresponding to the gate 32. The channel 34 may be formed using any material that is suitable for a conventional thin film transistor. For example, the channel 34 may be formed using a Zn oxide-based material, e.g., Zn oxide, InZn oxide, or GaInZn oxide.

Referring to FIG. 4D, a conductive material may be coated on the gate insulating layer 33 and the channel 34 to form a conductive layer, and then a portion of the conductive layer on the channel 34 may be etched to form a source 35a and a drain 35b. The source 35a and the drain 35b may be formed using a metal or a conductive metal oxide. For example, the metal may be Pt, Ru, Au, Ag, Mo, Al, W, or Cu, and the conductive metal oxide may be IZO (InZnO) or AZO (AlZnO).

Referring to FIG. 4E, a surface of the channel 34 may be etched to form a recession R. The recession R may be formed by etching a portion of the channel 34 which does not contact the source 35a and the drain 35b. To form the recession R, the Zn oxide-based material forming the channel 34 may be etched. Conventionally, a Zn oxide-based material may be etched using an aqueous solution of a hydrochloric acid (HCl), a hydrofluoric acid (HF), or a phosphoric acid (P₂O₅). An etching speed of the Zn oxide-based material may be controlled, but it may be difficult to adjust the thickness of a thin layer to be formed because the etching speed may be as high as about 20 nm/min or more. Accordingly, such an etching method may not be used to perform fine etching. According to example embodiments, an etchant including an acetic acid (CH₃COOH) may more easily control the etching speed of the Zn oxide-based material.

In example embodiments, a Zn oxide-based etchant may be an aqueous mixture solution of CH₃COOH and at least one of HCl, HF, and P₂O₅. The amount of the at least one of HCl, HF, and P₂O₅ may be in the range from about 0.1 to about 1 vol %, and the amount of CH₃COOH may be in the range from about 5 to about 50 vol %. A method of preparing the Zn oxide-based etchant according to example embodiments will now be described in detail. At least 1 ml of HCl, HF, or P₂O₅ may be mixed with at least 99 ml of deionized water to prepare a diluted acid. Then, at least 10 ml of CH₃COOH may be mixed with the diluted acid. When a Zn oxide is etched using the Zn oxide-based etchant according to example embodiments, the etching speed may be in the range from about 1 to about 8 nm/min and thus, the Zn oxide may be etched with a relatively high degree of precision. Accordingly, the recession R may be more easily formed by etching the channel 34 formed of Zn oxide using the Zn oxide-based etchant according to example embodiments.

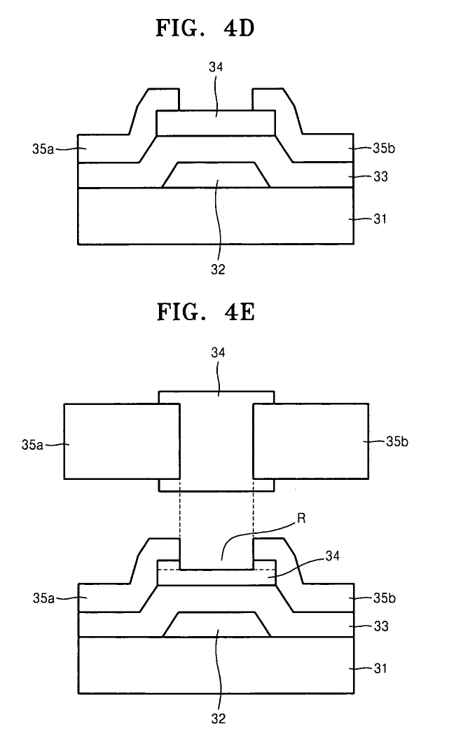

FIG. 5 is a graphical view of a drain current with respect to a gate voltage of a thin film transistor according to example embodiments. The thin film transistor used herein may include a SiO₂ layer about 100 nm thick formed on a Si substrate, a gate formed of Mo having a thickness of about 200 nm, a gate insulating layer formed of Si₃N₄ having a thickness of about 200 nm, a channel having a recession formed of GaInZn oxide having a thickness of about 70 nm, and source and drain formed of Ti/Pt. Referring to FIG. 5, an off current may be about 10⁻¹² A or lower, an on-current may be about 10⁻⁴ A, and thus, an on/off-current ratio may be about 10⁸ or more. For example, the thin film transistor may show an increased on/off current ratio and a decreased off-current, which may be characteristics required of a thin film transistor.

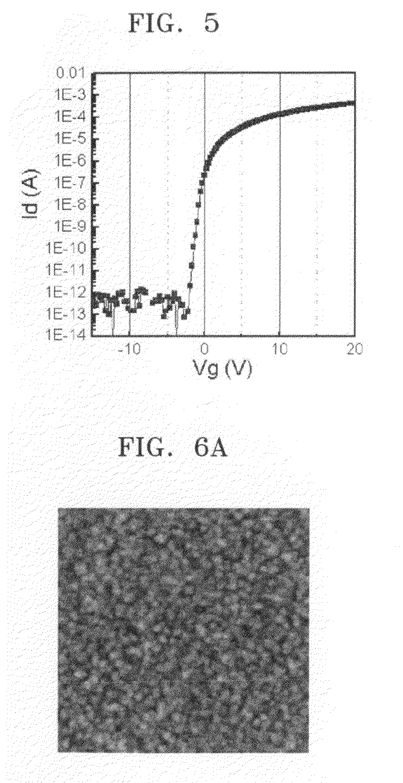

FIGS. 6A and 6B illustrate atomic force microscopic (AFM) images of the surface of a ZnO layer before and after a wet etching process is performed using a Zn oxide-based etchant according to example embodiments. FIG. 6A illustrates the surface of the ZnO before the wet etching process is performed, and the surface roughness measured may be about 0.286 nm (rms). FIG. 6B illustrates the surface of the ZnO after the wet etching process is performed, and the surface roughness measured may be about 0.829 nm (rms). Accordingly, the ZnO may be suitable for use in a thin film transistor.

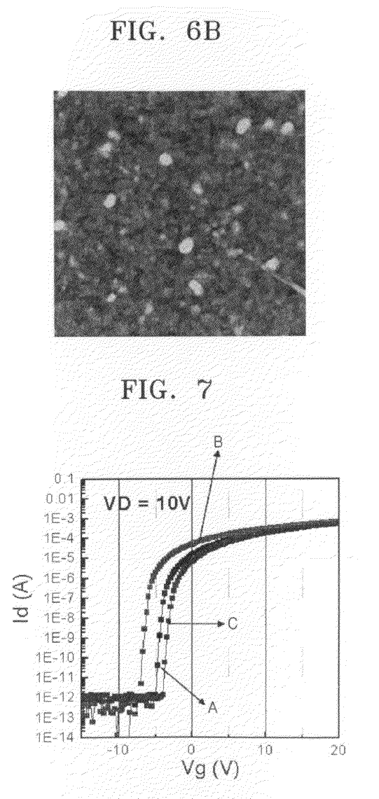

FIG. 7 is a graphical view illustrating humidity test results of a thin film transistor when the thin film transistor is etched using a Zn oxide-based etchant according to example embodiments. In FIG. 7, “A” shows electrical characteristics of a thin film transistor sample directly after the thin film transistor sample is formed, “B” shows electrical characteristics of the thin film transistor sample after the thin film transistor sample is left to sit in a humidity of about 95% for about 14 hours. “C” shows electrical characteristics of the thin film transistor sample when a Zn oxide channel of the thin film transistor sample which has been left to sit in humidity of about 95% is wet-etched using a Zn oxide-based etchant according to example embodiments.

Referring to FIG. 7, after the thin film transistor sample is left to sit in humidity of about 95% for about 14 hours, Vth may move in a direction of (−) voltage because the Zn oxide may be sensitive to humidity (A→B). Such a phenomenon may be generally seen when OH— is adsorbed to the surface of a channel of a thin film transistor to form a thin OH— membrane. However, when the surface of the channel of the thin film transistor is etched using a Zn oxide-based etchant according to example embodiments, initial characteristics might have been restored (B→C). For example, in the case of the Zn oxide-based etchant according to example embodiments, the etching speed of the Zn oxide may be controlled to be relatively low, so that an OH— adsorbed layer may be more easily removed while the channel of the thin film transistor may not be damaged.

A surface of the channel may be partially removed to form a recession. Therefore, a damaged region, which may be formed in a channel when a source and drain are formed according to a conventional method, may be removed. Thus, a thin film transistor having improved electrical properties may be fabricated. Example embodiments may provide an etchant where an etching speed of a zinc oxide-based material forming a channel of a thin film transistor may be more easily controlled.

While example embodiments have been particularly shown and described with reference to exemplary embodiments thereof, it will be understood by those of ordinary skill in the art that various changes in form and details may be made therein without departing from the spirit and scope of example embodiments as defined by the following claims.

What is claimed is:

1. A zinc oxide-based etchant comprising an aqueous mixture solution of CH₃COOH and at least one of HCl, HF, and P₂O₅.

2. The zinc oxide-based etchant of claim 1, wherein the amount of the at least one of HCl, HF, and P₂O₅ is in the range from about 0.1 to about 1 vol %.

3. The zinc oxide-based etchant of claim 1, wherein the amount of CH₃COOH is in the range from about 5 to about 50 vol %.

4. A zinc (Zn) oxide-based thin film transistor comprising:
a gate;
a gate insulating layer on the gate;
a channel including zinc oxide on a portion of the gate insulating layer; and
a source and drain contacting sides of the channel;
the channel further including a recession between the source and drain.

5. The zinc oxide-based thin film transistor of claim 4, wherein the recession has a step with respect to portions of the channel contacting the source and the drain.

6. The zinc oxide-based thin film transistor of claim 4, wherein the recession is formed by a wet etching process using a zinc oxide-base etchant including an aqueous mixture solution of CH₃COOH and at least one of HCl, HF, and P₂O₅.

7. The zinc oxide-based thin film transistor of claim 6, wherein the amount of the at least one of HCl, HF, and P₂O₅ is in the range from about 0.1 to about 1 vol %.

8. The zinc oxide-based thin film transistor of claim 6, wherein the amount of CH₃COOH is in the range of about 5 to about 50 vol %.

9. The zinc oxide-based thin film transistor of claim 4, wherein the zinc oxide is ZnO, InZnO, or GaInZnO.

10. A method of fabricating a thin film transistor, the method comprising:
forming a gate;
forming a gate insulating layer on the gate;
forming a channel including zinc oxide on a portion of the gate insulating layer;
forming a source and drain by coating a conductive material on the gate insulating layer and the channel and etching the conductive material on the channel; and
forming a recession by etching a surface of the channel exposed between the source and the drain.

11. The method of claim 10, wherein forming the recession includes providing a step with respect to portions of the channel contacting the source and drain.

12. The method of claim 10, wherein the zinc oxide is ZnO, InZnO, or GaInZnO.

13. The method of claim 12, wherein forming the recession by etching includes a wet etching process using a zinc oxide-based etchant including an aqueous mixture solution of CH₃COOH and at least one of HCl, HF, and P₂O₅.

14. The method of claim 13, wherein the amount of the at least one of HCl, HF, and P₂O₅ is in the range from about 0.1 to about 1 vol %.

15. The method of claim 13, wherein the amount of CH₃COOH is in the range from about 5 to about 50 vol %.

16. A method of forming a zinc oxide-based etchant comprising:
mixing at least one of HCl, HF, and P₂O₅ with deionized water; and
mixing CH₃COOH with the mixture of at least one of HCl, HF, and P₂O₅ and deionized water.

17. The method of claim 16, wherein the amount of the at least one of HCl, HF, and P₂O₅ is at least 1 ml and the deionized water is at least 99 ml in the zinc oxide-based etchant.

18. The method of claim 16, wherein at least 10 ml of the CH₃COOH is mixed with the mixture of at least one of HCl, HF, and P₂O₅ and deionized water.

19. The method of claim 16, wherein the amount of the at least one of HCl, HF, and P₂O₅ is in the range from about 0.1 to about 1 vol %.

20. The method of claim 16, wherein the amount of the CH₃COOH is in the range from about 5 to about 50 vol %.
